(19) United States
(12) Patent Application Publication
(10) Pub. No.: US 2009/0115643 A1
(43) Pub. Date: May 7, 2009

(54) Finger-Tip Key Depressor And Method For Using The Same

(76) Inventor: Joel H. Goffman, Houston, TX (US)

Correspondence Address: LOCKE LORD BISSELL & LIDDELL LLP;ATTN: IP DOCKETING, 600 TRAVIS, SUITE 3400, HOUSTON, TX, 77002-3095, US

(21) Appl. No.: 12/265,030

(22) Filed: Nov. 5, 2008

Related U.S. Application Data
(60) Provisional application No. 60/996,154, filed on Nov. 5, 2007.

(51) Int. Cl. H03K 17/94

(52) U.S. Cl. 341/22

(57) ABSTRACT

An apparatus to fit on the digit of a hand to aid the user of an electronic handheld device to depress at least a portion of a key on the keypad of an electronic handheld device that comprises an elongated hollow member with a proximal end and a distal end, the hollow member being sized to fit over a the digit of a hand, wherein the proximal end is open, wherein a substantially rigid tip extends from the distal end, and wherein said substantially rigid tip is sized to depress at least a portion of an individual key on the keypad of a handheld electronic device. Methods for using the apparatus and for encouraging individuals to use the apparatus for depressing at least a portion of a key on the keypad of an electronic handheld device are also disclosed and claimed.

### CROSS REFERENCE TO RELATED APPLICATIONS

The present application claims priority to U.S. Provisional Patent Application Ser. No. 60/996,154, filed Nov. 5, 2007, the contents of which are incorporated herein by reference in its entirety.

### STATEMENT REGARDING FEDERALLY SPONSORED RESEARCH OR DEVELOPMENT

Not applicable.

### REFERENCE TO APPENDIX

Not applicable.

### BACKGROUND OF THE INVENTION

1. Field of the Invention

The inventions disclosed and taught herein relate generally to an apparatus and method for using a handheld electronic device, and more specifically are related to apparatii and methods for accurately pressing keys on the keypad of a handheld electronic device, with potentially reduced tendency for repetitive stress injuries associated with the use of such handheld electronic devices.

2. Description of the Related Art

Advancing technology in microelectronics, power, and functional integration has allowed a continuous and accelerating rate of decline in the size of consumer electronics. One area in which the decreasing size of devices coupled with increasing functionality is most apparent is in handheld electronics, such as cellular telephones, messaging devices, personal data assistants (PDAs), BLACKBERRY® and similar devices (those wireless, handheld instruments which enable “on the go” e-mail, internet browsing, word processing, telephone and text messaging as well as other information services), and so-called “smart phones.” However, as these handheld electronic devices become ever-smaller, some users are finding it increasingly difficult to enter data into these devices in a convenient and accurate manner. Additionally, as these devices have decreased in size, there has been an associated increase in medical conditions linked to the non-ergonomic use of the devices themselves, including “Trigger Thumb,” Carpal Tunnel Syndrome, and DeQuervain's tenosynovitis.

With regard to these medical conditions associated with the use of such handheld electronic devices, the first problem is that the thumb is not designed to be dextrous, and on an ordinary keyboard, the use of the thumb is normally limited in its movement. The thumb's main role, situated as it is lower down on the side of the hand, at almost right angles to the fingers and with only one joint, is to enable a “strong pinch grip” with a finger. However, the design of the BLACKBERRY® (and similar devices) means that most people use their thumbs to strike the key; and equivalent repetitive movements are more likely to put strain on the thumb than an equal number of movements on the fingers. BLACKBERRY® and similar devices may encourage over use, such as unlimited texting packages, as the number of words that can be used is unlimited, thus encouraging repetitive movements for longer periods of time.

Employing a device that encourages inappropriate thumb postures and fosters over usage could lead to symptoms of pain and swelling as a result of constant stretching and rubbing of tendons over the thumb joint. Potentially, over usage could lead to the development of more serious conditions such as the afore-mentioned “Trigger thumb,” “DeQuervain's tenosynovitis” and “carpal tunnel syndrome” (CTS), all of which can be difficult to resolve therapeutically and increase the user's susceptibility to recurrence. BLACKBERRY® and similar handheld, keyboard-based device usage can also aggravate pre-existing medical conditions, such as arthritis, and in some instances has been associated with temporary visual fatigue.

Currently available handheld electronic devices come equipped with a variety of data entry interfaces. Some devices are equipped with a touch screen for user interaction with the device, usually have a detachable stylus that can be used on the touch screen. Interaction is then done by tapping the screen to activate buttons or menu choices, and dragging the stylus to, for example, highlight text. The stylus may also be used to enter data to the handheld device through a virtual (“soft”) keyboard on the touch screen.

Styluses have been developed to attach to the finger of the user, acting as an artificial finger tip for entering commands and data into a personal data device, such as an electronic notebook, by contacting the screen of the personal data device. The operator comprises a partially rigid base which encircles the finger, generally conforming to the finger, and a rigid tip member which projects forwardly from the base to contact the screen. The tip of the tip member is of reduced diameter at the point of contact with the screen. The tip member has a snap fitting connector enabling it to be manually and removably attached to the base. The base is tubular and has a plurality of sockets, and the tip member has an equivalent number of male elements snap fitting to the sockets.

In other applications, an adjustable and economical finger stylus has been developed for operating a touch sensitive screen and for entering data in, e.g., a PDA. The adjustable elements of the finger stylus provide for rapid, convenient and significant adjustability while comfortably securing the stylus to the finger during use. Once sized, the stylus can readily be slipped on and off the user's finger as needed.

Other handheld electronic devices, most notably the so-called “smart phones,” may not contain a touch screen, but rather are equipped with a small keyboard or other keypad. Many smart phones are equipped with a full QWERTY-type keyboard such as U.S. Pat. No. 207,559, containing as many as thirty-five keys, or more. Even standard cellular telephones now contain at least fifteen separate keys on a keypad. As these and other hand-held electronic devices get smaller, users find they have an increasingly difficult time using these keys accurately. Users experience increasing difficulty in using the keypad to interface with a handheld electronic device where the device requires or allows for depressing different portions of a single key for the entry of various information values.

The inventions disclosed and taught herein are directed to an apparatus to fit on the end of a digit of a hand that can be used to assist in pressing keys on a keypad of a handheld electronic device, while simultaneously minimizing the physiological problems which can be associated with the ergonomic use of such devices. Also disclosed and taught herein are methods for using the apparatus for assisting in depressing at least part of a key on a keypad of a handheld electronic device, as well as methods for encouraging the use of the apparatus for assisting in depressing at least part of a key on a keypad of a handheld electronic device.

### BRIEF SUMMARY OF THE INVENTION

In certain embodiments of the invention, an apparatus to fit on one or more digits of a hand to aid the user of an electronic handheld device is described, wherein the apparatus comprises an elongated hollow member with a proximal end and a distal end, the hollow member being sized to fit over a the digit of a hand, wherein the proximal end is open. A substantially rigid tip extends from the distal end, and may be sized to depress at least a portion of an individual key on the keypad of a handheld electronic device.

In further accordance with this embodiment of the present disclosure, the elongated hollow member may be sized to cover the terminal or intermediate phalanges of a finger, or the distal or proximal phalanges of the thumb. It may be closed, partially-closed, or open at the distal end, and may be composed of an elastically-resilient material and/or vented or porous to water vapor.

In a further embodiment of the present disclosure, the apparatus may be used as part of a method for typing on a handheld electronic device. Such a method would comprise placing the apparatus on a digit of the hand and depressing at least a portion of a key on the keypad of an electronic handheld device.

In yet another embodiment of the present disclosure, the apparatus described herein may also be used as part of a method of encouraging individuals to use the device to assist in depressing at least a portion of a key on the keypad of a handheld electronic device. Such a method may comprise the steps of providing the device and providing instructions on how to use the device to assist in depressing at least a portion of a key on the keypad of an electronic device.

### BRIEF DESCRIPTION OF THE SEVERAL VIEWS OF THE DRAWINGS

The following figures form part of the present specification and are included to further demonstrate certain aspects of the present invention. The invention may be better understood by reference to one or more of these figures in combination with the detailed description of specific embodiments presented herein.

FIG. 1 illustrates a perspective side view of one embodiment of the invention, showing an hollow member with a substantially rigid tip extending from the closed distal end.

FIG. 2 illustrates a top-view of the embodiment of the invention shown in FIG. 1.

FIG. 3 illustrates a cut-away side view of the embodiment taken along line 3-3 of the invention shown in FIG. 2.

FIG. 4 illustrates a perspective side view of an alternate embodiment of the invention, showing an hollow member with a substantially rigid tip extending from the open distal end.

FIG. 5 illustrates a top-view the alternate embodiment of the invention shown in FIG. 4.

FIG. 6 illustrates a cut-away side view taken along line 6-6 of the alternate preferred embodiment of the invention shown in FIG. 5.

FIG. 7 illustrates a perspective side view of an alternate embodiment of the invention, showing a shortened hollow member with a substantially rigid tip extending from the closed distal end.

FIG. 8 illustrates a top-view of the alternate embodiment of the invention shown in FIG. 7.

FIG. 9 illustrates a cut-away side view taken along line 9-9 of the alternate embodiment of the invention shown in FIG. 7.

FIG. 10 illustrates a perspective view of an alternate embodiment of the invention, showing a shortened hollow member with a substantially rigid tip extending from the partially-closed distal end.

FIG. 11 illustrates an alternate perspective view of the alternate preferred embodiment of the invention shown in FIG. 10.

FIG. 12 illustrates a perspective view of an alternate embodiment of the invention, showing a shortened hollow member with a substantially rigid tip extending from the side.

While the inventions disclosed herein are susceptible to various modifications and alternative forms, only a few specific embodiments have been shown by way of example in the drawings and are described in detail below. The figures and detailed descriptions of these specific embodiments are not intended to limit the breadth or scope of the inventive concepts or the appended claims in any manner. Rather, the figures and detailed written descriptions are provided to illustrate the inventive concepts to a person of ordinary skill in the art and to enable such person to make and use the inventive concepts.

### DETAILED DESCRIPTION

The Figures described above, and the written description of specific structures and functions below, are not presented to limit the scope of what Applicants have invented or the scope of the appended claims. Rather, the Figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of the present disclosure. It must be understood that the inventions disclosed and taught herein are susceptible to numerous and various modifications and alternative forms. Lastly, the use of a singular term, such as, but not limited to, “a,” is not intended as limiting of the number of items. Also, the use of relational terms, such as, but not limited to, “top,” “bottom,” “left,” “right,” “upper,” “lower,” “down,” “up,” “side,” and the like are used in the written description for clarity in specific reference to the Figures and are not intended to limit the scope of the invention or the appended claims.

Applicant has created an apparatus to fit on the digit of a hand to aid the user of an electronic handheld device to depress at least a portion of a key on the keypad of an electronic handheld device. The apparatus comprises an elongated hollow member with a proximal end and a distal end, the hollow member being sized to fit over a the digit of a hand, wherein the proximal end is open, wherein a substantially rigid tip extends from the distal end, and wherein said substantially rigid tip is sized to depress at least a portion of an individual key on the keypad of a handheld electronic device.

The hollow member may be sized to cover the terminal or intermediate phalanges of a finger, or the distal or proximal phalanges of the thumb. It may be closed or open at the distal end, and may be composed of an elastically-resilient material and/or vented or porous to water vapor.

The finger-tip key depressor apparatus may be used as part of a method for typing on a handheld electronic device. Such a method would comprise placing the apparatus on a digit of the hand and depressing at least a portion of a key on the keypad of an electronic handheld device.

The apparatus may also be used as part of a method of encouraging individuals to use the device to assist in depressing at least a portion of a key on the keypad of a handheld electronic device. Such a method would comprise the steps of providing the device and providing instructions on how to use the device to assist in depressing at least a portion of a key on the keypad of an electronic device.

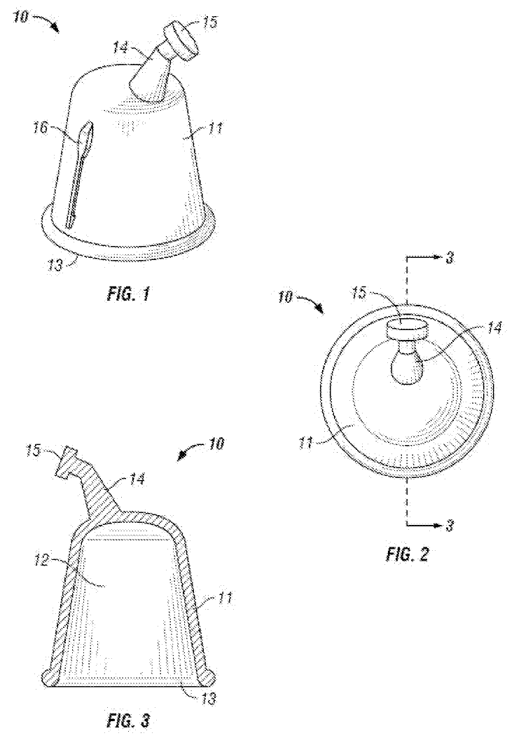

Turning now to the figures, FIGS. 1-3 are illustrations of a particular embodiment of the present invention, showing an apparatus suitable for use in assisting the user of an electronic handheld device to depress at least a portion of a key on a keypad of the device. FIGS. 1-3 illustrate a hollow member 10, which may comprise, for example, a cylinder, tube of oval form, or other shape. In the embodiment illustrated in FIGS. 1-3, in particular in the perspective view of FIG. 1, the hollow member 10 is shown to be a tube of generally oval form, and is formed by an annular wall 11 defining an elongated inner bore 12, shown in FIG. 3, a cross-sectional view of the top-down view of the apparatus 10 of FIG. 2, taken along line 3-3. As can be seen therein, and as will be described in more detail below, inner bore 12 defines a space wherein a users digit may extend into bore 12, such that the end of the user's digit is substantially circumscribed by apparatus 10.

The proximal end should be open to allow for the insertion of a digit of a hand. The opening at the proximal end 13 should therefore be sized to fit around the digit of a hand. In practice, the apparatus may be offered in various sizes to accommodate different sized digits on the hands of a single user, or to allow for the use by various users with hand of various sizes.

The hollow member 10 can be closed around the circumference or partially open on a side. If closed, the wall could have one or more vent holes disposed within. The vent holes allow for ease in inserting or removing the digit of the hand so as to prevent air from being trapped therein. Such vent holes also allow for the digit of the hand to “breathe” increasing the comfort of the user.

Any suitable material could be employed to make the apparatus. The hollow member 10 can be composed of any of a variety of materials such as, for example, plastic, urethane, rubber, a combination plastic-rubber material, or metal alloy. Any suitable method of manufacture could be employed to make the apparatus, such as injection molding. The material used in the hollow member can affect the users experience when typing or otherwise depressing keys on the keypad of an electronic handheld device. In some embodiments, the hollow member 10 may be composed of an elastic material such as a synthetic rubber that would permit a degree of flexibility. Such flexibility can assist in allowing for a comfortable fit for the user while preventing the hollow member 10 from slipping off the digit of the hand during use. A flexible material would also be important if the hollow member we sized to extend to the intermediate phalange of a finger or the proximal phalange of a thumb. However, composing the hollow member 10 of an elastic material may increase the difficulty or time required for a user to insert a digit of the hand into the hollow member.

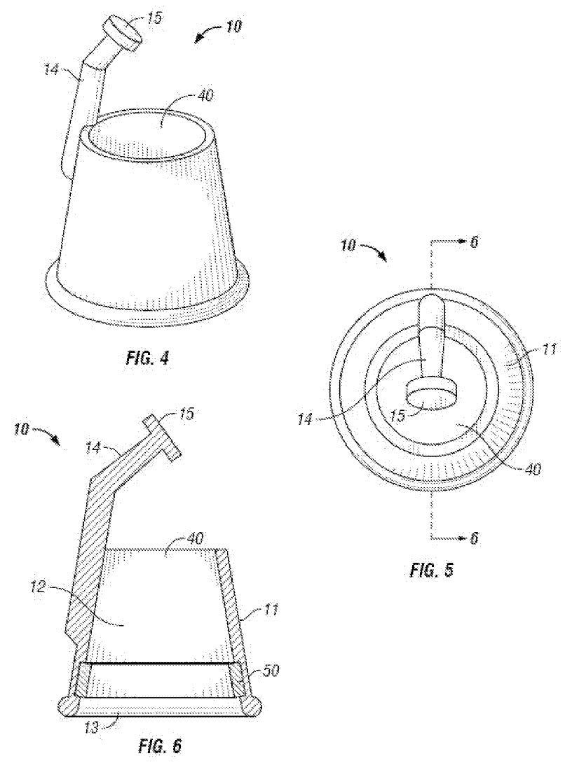

Alternatively, as illustrated in FIGS. 4-6, the hollow member 10 may be composed of a rigid or semi-rigid material, such as a rigid plastic or resin or a metal or metal alloy. In such an embodiment, hollow member 10 is also formed by an annular wall 11 defining an elongated bore 12 and is open at the proximal end 13. In such an embodiment, the insertion of a digit of the hand into the hollow member may be easier because of the rigid material comprising the hollow member 10, but additional features may be required to ensure a snug fit on the digit of the hand. As shown in FIG. 5, such an additional feature may be, for example, a strip of rubber lining 50 around the interior of the annular wall at or near the proximal end of the hollow member. The strip of rubber or other similar material will contact the digit of the hand and prevent slippage of the hollow member 10 during use. It should be noted that the use of a rigid or elastic material to form the hollow member 10 is independent from other features of the embodiment discussed herein.

Returning to FIGS. 1-3, a substantially rigid tip 14 extends from the end of the hollow member. For purposes of this invention, “substantially rigid” denotes that the identified element, while rigid, is capable of some flexibility if grasped and manually flexed, but it is sufficiently rigid or firm so as to permit the user to depress a key on the keypad of a handheld electronic device without undue bending of the tip, where such undue bending would interfere with is convenient use to depress at least a portion of a key.

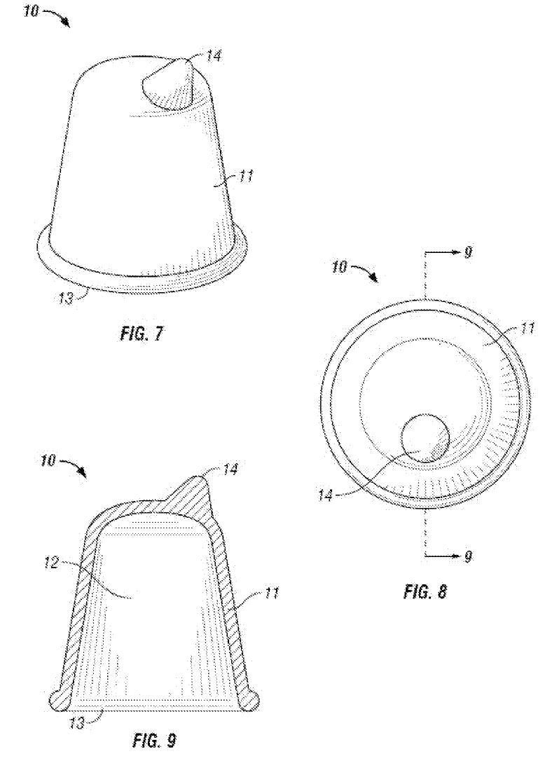

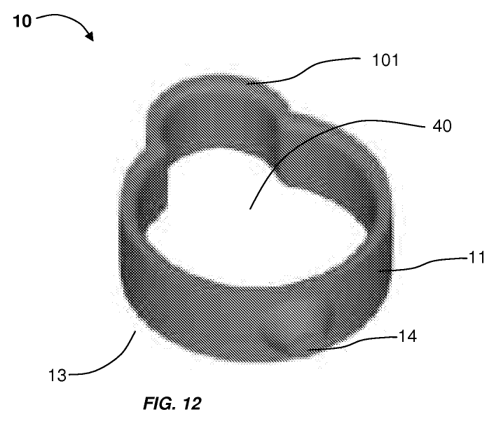

The substantially rigid tip may be straight or curved, and should be of a length that permits the user to accurately and comfortably depress keys on a keypad. As one alternative example to the substantially rigid tip 14 depicted in FIGS. 1-3, the substantially rigid tip 14 may be comprised of a nub of material that is relatively short compared to the length of the hollow member 10, as depicted in FIGS. 7-12. In some embodiments, as illustrated in FIG. 12, the substantially rigid tip 14 may be situated to extend from the side of the hollow member 10. In other embodiments, not pictured, the substantially rigid tip 14 may be constructed to allow the user of the apparatus to trim the length of the substantially rigid tip 14 to a preferred length depending on the user's hand size and the configuration of the handheld electronic device with which the apparatus is intended to be used.

The substantially rigid tip 14 may be composed of the same material as the hollow member and produced as a single piece. Alternatively, the substantially rigid tip 14 may be composed of a different material that has more desirable attributes for the present application and affixed securely to the hollow member using appropriate manufacturing techniques.

The end of the substantially rigid tip 14 may comprise a non-slip pad 15, shield or other material to promote secure contact between the substantially rigid tip and the key on a keypad. This pad 15 would ideally be comprised of a material that would possess a high friction coefficient but would be of a material that would not mar, scratch, or otherwise damage the key on the keypad to which it was applied during use.

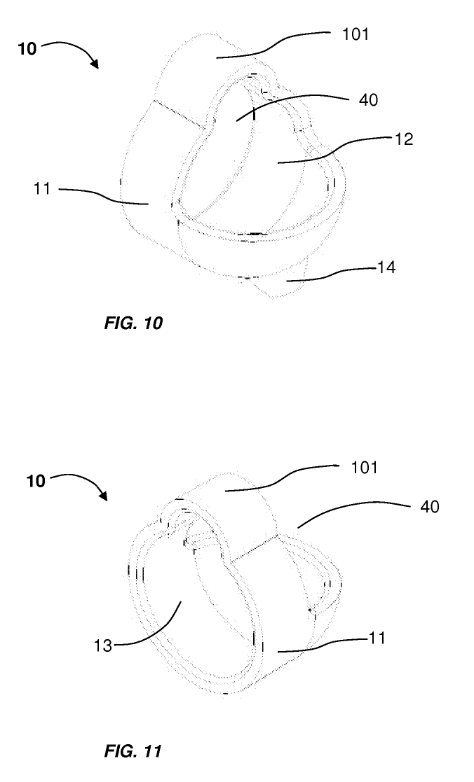

The distal end of the hollow member may be closed, as illustrated in FIGS. 1-3 and FIGS. 7-9, or open, as illustrated in FIGS. 4-6 and FIG. 12. The opening 40 at the distal end may be fully or partially opened. Where partially opened, as illustrated in FIGS. 10-11, the distal end of the hollow member 10 can provide a structure against which the end of the inserted digit can rest, allowing for increased control while using the apparatus.

In some preferred embodiments, the hollow member 10 may be designed with one of many available features to aid in the fit and ease of inserted of a digit of the hand. One such feature is depicted in FIGS. 10-12, and includes an expander 101 (expanding region) that bridges the two side walls of the hollow member and allows the hollow member to accommodate a wider digit of the hand. The expander 101 also increases the ease of inserting a digit of the hand into the open proximal end 13 of the hollow member 10.

In some preferred embodiments, the hollow member 10 may be equipped with a clip 16, as shown in FIG. 1. Such a clip would allow the user to securely store the apparatus, e.g., on a pocket or a bag or neck strap when it is not in use.

The apparatus that is part of the present invention can be used as part of a method of typing on a handheld electronic device. The user would fit the hollow member of the apparatus on a digit of the user's hand with the substantially rigid tip pointing away from the hand and extending from the distal end of the digit. The user would then use the substantially rigid tip to depress as least a portion of a key on the keypad of the handheld electronic device.

In some applications, a user may choose to use an apparatus on more than one digit of a hand, and/or on one or more digits of both of the user's hands. The determination concerning the number used and the placement of each apparatus will depend on user preferences and/or on the design and layout of the handheld electronic device to which the apparatus is applied.

The apparatus of the present invention can also be used as part of a method of encouraging individuals to use the apparatus to assist in depressing at least a portion of a key on the keypad of a handheld electronic device. Such instructions may be contained on or within the packaging material, or, in some applications, may be accessed via the Internet. Instructions can be written in a step-by-step method, or may entail merely a diagram, photograph, or other graphic illustrating the use of the apparatus to assist in typing on the keypad of a handheld electronic device.

Other and further embodiments utilizing one or more aspects of the inventions described above can be devised without departing from the spirit of the claimed invention. For example, the method of encouraging the use of an apparatus to assist in depressing at least a portion of a key on a handheld electronic device can be used to encourage to use of certain sewing thimbles or thimble-style scleral depressors in the claimed manner. Further, the various methods and embodiments of the finger-tip key depressor can be included in combination with each other to produce variations of the disclosed methods and embodiments. Discussion of singular elements can include plural elements and vice-versa.

The order of steps can occur in a variety of sequences unless otherwise specifically limited. The various steps described herein can be combined with other steps, interlineated with the stated steps, and/or split into multiple steps. Similarly, elements have been described functionally and can be embodied as separate components or can be combined into components having multiple functions.

The inventions have been described in the context of preferred and other embodiments and not every embodiment of the invention has been described. Obvious modifications and alterations to the described embodiments are available to those of ordinary skill in the art. The disclosed and undisclosed embodiments are not intended to limit or restrict the scope or applicability of the invention conceived of by the Applicants, but rather, in conformity with the patent laws, Applicants intend to fully protect all such modifications and improvements that come within the scope or range of equivalent of the following claims.

What is claimed is:

1. A device to fit on the digit of a hand to aid a user of an electronic handheld device, the device comprising:
a hollow member with a proximal end and a spaced apart distal end;
a wall positioned between the proximal end and the distal end, extending in a circumferential path that forms a closed, interior region;
the hollow member being sized to fit over a the digit of a hand;
wherein the proximal end is open;
wherein a substantially rigid tip extends from the hollow member; and
wherein said substantially rigid tip is sized to depress at least a portion of an individual key on the keypad of a handheld electronic device.

2. The apparatus of claim 1 wherein the end of the substantially rigid tip is composed of a non-slip material.

3. The apparatus of claim 1 wherein the hollow member is sized to cover: (a) the terminal or intermediate phalanges of a finger, or (b) the distal or proximal phalanges of a thumb.

4. The apparatus of claim 1 wherein the hollow member contains an extending region.

5. The apparatus of claim 1 wherein the hollow member is open at the distal end.

6. The apparatus of claim 1 wherein the hollow member is partially-closed at the distal end.

7. The apparatus of claim 1 wherein the substantially rigid tip extends from the distal end of the hollow member.

8. The apparatus of claim 1 wherein the hollow member is closed at the distal end.

9. The apparatus of claim 1 wherein the hollow member is constructed of an elastically resilient material.

10. The apparatus of claim 1 wherein the hollow member contains vent holes or is constructed of a material that is permeable to water vapor.

11. The apparatus of claim 1 wherein a clip is affixed to the hollow member.

12. A method of depressing keys on a handheld electronic device comprising:
(a) placing an apparatus on a digit of the hand, wherein the apparatus comprises:
A hollow member comprising a proximal end and a distal end,
wherein the proximal end of the hollow member is open to permit the insertion of the digit of the hand, and
wherein a substantially rigid tip extends from the hollow member; and
(b) depressing at least a portion of a key on the keypad of an electronic handheld device.

13. The method of claim 12 wherein the hollow member is constructed of an elastically resilient material permitting a comfortable fit around the digit of the hand of the wearer.

14. The method of claim 12 wherein the end of the substantially rigid tip is composed of a non-slip material.

15. The method of claim 12 wherein the hollow member contains an extending region.

16. The method of claim 12 wherein the hollow member is open at the distal end.

17. The method of claim 12 wherein the hollow member is partially-closed at the distal end.

18. The method of claim 12 wherein the substantially rigid tip extends from the distal end of the hollow member.

19. The method of claim 12 wherein the hollow member is closed at the distal end.

20. The method of claim 12 wherein the hollow member is sized to cover (a) the terminal or intermediate phalanges of a finger of the user, or (b) the distal and proximal phalanges of a thumb of the user.

21. The method of claim 12 wherein the hollow member contains vent holes and/or is composed of a non-slip material.

22. A method of encouraging individuals to use an apparatus to assist in depressing at least a portion of a key on the keypad of a handheld electronic device, comprising the steps of:
(a) providing an apparatus to assist a user to depress a key on a handheld electronic device, the provided device comprising:
an elongated hollow member with a proximal end and a distal end;
the hollow member being sized to fit over a the digit of a hand;
wherein the proximal end is open;
wherein a substantially rigid tip extends from the distal end;
and wherein said substantially rigid tip is sized to depress at least a portion of an individual key on the keypad of a handheld electronic device.
(b) providing instructions on how to use the apparatus to assist in depressing at least a portion of a key on the keypad of an electronic handheld device.

23. The method of claim 22 further comprising offering the apparatus for sale in at least two sizes such that each size apparatus can fit over the tip of a digit of a hand of a different diameter.

24. The method of claim 22 wherein the handheld electronic device is a cellular telephone.

25. The method of claim 22 wherein the handheld electronic device includes a full or abbreviated QWERTY keyboard.

26. The method of claim 22 further comprising making the instructions available electronically via the Internet.

27. An apparatus for assisting a user of a handheld electronic device having a keyboard of the QWERTY-style with the depression of the keys on the keyboard, the apparatus comprising:
covering means for covering at least a portion of a user's digit; and
depressing means for depressing one or more keys of the electronic device's keyboard when the user acts to depress a key during operation of the handheld electronic device.
